(19) United States
(12) Patent Application Publication
(10) Pub. No.: US 2008/0176407 A1
(43) Pub. Date: Jul. 24, 2008

(54) Method of manufacturing semiconductor device

(75) Inventor: Yutaka Nagakura, Kumamoto (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC ELECTRONICS CORPORATION, Kawasaki (JP)

(21) Appl. No.: 12/010,287

(22) Filed: Jan. 23, 2008

(30) Foreign Application Priority Data
Jan. 24, 2007 (JP) 13707/2007

(51) Int. Cl. H01L 21/311

(52) U.S. Cl. 438/703; 257/E21.249

(57) ABSTRACT

A semiconductor device manufacturing method includes: a step of implementing etching onto a film formed on a semiconductor wafer; and a removal step of supplying, after etching, a removing solution for removing deposition on the film to a semiconductor wafer in the state where the number of rotations thereof is smaller than a predetermined number of rotations thereafter to rotate the semiconductor wafer at a higher number of rotations, which is greater than the predetermined number of rotations. In this method, the time during which removing solution is supplied is 45 sec. or less. This method includes a sequence in which removal step is executed twice or more.

### BACKGROUND OF THE INVENTION

The present invention relates to a technology for manufacturing a semiconductor device. In particular, the present invention relates to a technology for removing residue of photoresist in a manufacturing process for a semiconductor device.

When a circuit pattern illustrated on LSI is formed on a semiconductor wafer, a transistor, an insulating film, and a metallic wiring pattern for connecting elements including transistor are formed on the semiconductor wafer.

FIG. 1 is a flowchart schematically showing a manufacturing process of a semiconductor circuit pattern. A metallic wiring film is formed by, e.g., sputtering process on an underlying insulating film (S101) having some elements including transistor on a semiconductor wafer. Photoresist is applied on the metallic wiring film by a photoresist coater (S102). By an exposure tool, reticle pattern for metallic wiring pattern is exposed onto the photoresist (S103). By processing photoresist film by developer, the exposed part of photoresist is removed, and the part which has not been exposed is left on the metallic wiring film (S104). By using the left photoresist as a mask, dry etching process is performed. Thus, the metallic wiring film of the part where there is no photoresist is removed (S105). The left metallic wiring film forms a circuit pattern. Thus, photoresist is left on the metallic wiring film. The left photoresist is removed through two-step removal process of plasma ashing and wet cleaning as described below. By plasma ashing, photoresist surface layer which has been hardened by attacking of plasma at the time of dry etching is removed (S106). In the wet cleaning step after plasma ashing, the left photoresist layer is dissolved by using organic solvent. Thus, the left photoresist is removed (S107). After the organic solvent has been removed, the wafer is dried. By the above-mentioned process steps, a metallic wiring pattern is formed. An insulating film is formed on the metallic wiring pattern (S108). The present invention particularly relates to the wet cleaning process among these process steps.

In the Japanese Patent Laid-Open No. 2003-092280, there is described a wafer drying method applied for drying a wafer to be processed after the wafer has undergone processing by processing solution. FIG. 2 shows a wafer processing apparatus described in this Document. The wafer processing apparatus mainly includes a spin chuck 101 for rotating a wafer W in the state where the wafer W is held in a horizontal direction, a rotation mechanism 103 for rotating the spin chuck at a high speed, nozzles N1, N2, N3 for discharging cleaning solution or rinsing solution onto the wafer, lines 123, 124, 125, and tanks 121, 122, etc.

FIG. 3 shows the wafer processing method described in the Japanese Patent Laid-Open No. 2003-092280. For a time period from time t1 to t2, cleaning solution is discharged onto wafer. For a time period from t2 to t3, rinsing processing is performed. Thereafter, the number of rotations is increased. As a result, droplets are shaken off. Thus, the wafer is dried.

In the Japanese Patent Laid-Open No. 2001-070861, there is described a solution processing method for solving the problem that processing solution staying on the surface of a wafer is difficult to be replaced by a new processing solution so that chemical reaction on the surface of the wafer is lowered. In accordance with claim 1 of this document, this solution processing method includes a step of supplying processing solution to a material to be processed to allow the processing solution to come into contact with the surface of the material to be processed, and a step of removing processing solution in contact with the surface of the material to be processed, and is adapted to sequentially and repeatedly perform these steps.

In the Japanese Patent Laid-Open No. 2001-237214, there are described a wafer processing method and a wafer processing apparatus which are aiming at allowing processing within processing plane surface of wafer to be uniform thus to improve processing accuracy of etching processing and cleaning processing, etc. The wafer processing method described in the claim 1 of this patent document is a wafer processing method of performing a predetermined processing with respect to a wafer, which includes: a first processing step of supplying a first processing solution to the wafer while rotating the wafer at a first number of rotations; a second processing step of rotating the wafer at a second number of rotations, which is lower than the first number of rotations, in the state where no processing solution is supplied to the wafer; and a third processing step of supplying a second processing solution different from the first processing solution to the wafer while rotating the wafer at a third number of rotations, which is higher than the second number of rotations.

In the Japanese Patent Laid-Open No. 2002-164324, there is described a semiconductor device manufacturing method, which includes a cleaning step of removing protective deposition film containing reaction product produced at the time of etching a metallic layer.

In the Japanese Patent Laid-Open No. 2003-273064, there are described an apparatus for removing deposition and a method of removing deposition. In this removal method, the following steps are implemented in the state where a semiconductor wafer is rotating: cleaning solution is supplied onto the semiconductor wafer, and supply of cleaning solution is then stopped so that the cleaning solution on the semiconductor wafer is thus splashed; and pure water is supplied onto the semiconductor wafer so that the semiconductor wafer is cleaned; and supply of the pure water is stopped so that the pure water on the semiconductor wafer is splashed. These process steps are repeated in accordance with the degree of cleanness of the surface of the semiconductor wafer.

In the Japanese Patent Laid-Open No. 2002-158206, there is described a method of removing photoresist residue, including: successively repeating, two times or more, processing sequence including a step of removal-processing a wafer by fluorine based remover.

However, the inventor of the present invention has noticed that there are the following problems. In plasma ashing or wet cleaning, it is required to remove photoresist residue, and to remove reaction deposition which is deposition deposited as the result of the fact that reaction product at the time of dry etching is attached to a metallic wiring film. When removal of reaction deposition is insufficient, there is the possibility that when any other factor is added, the metallic wiring film may be corroded. The corroded part becomes high resistance material or insulating material. For this reason, there is the possibility that LSI may not normally operate. Accordingly, it is required that reaction deposition is sufficiently removed in the removal process.

FIG. 4 is a perspective view showing an example of metallic wiring pattern. Aluminum wires 204 are formed on an insulating film 202. Each aluminum wire 204 includes an upper surface part which is the surface of the side away from the insulating film 202, and a side surface parts 206 adjacent to the insulating film 202 and the upper surface part. The part in the vicinity of a line in parallel to extending direction of the aluminum wire 204 where the upper surface part and the side surface part 206 are in contact with each other is a corner part 210. Reaction deposition is apt to be attached to the part in the vicinity of upper surface central part 208, side surface parts 206 and corner parts 210. This circumstance is similar also in the case of metallic wiring other than aluminum.

In recent years, realization of high density of LSI circuit and realization of ultra fine structure of circuit pattern have been developed. As a result, width of gaps between metallic wires becomes shorter. A metallic wiring pattern caused to be of high density and of ultra fine structure which has been illustrated by the same scale as that of FIG. 4 is shown in FIG. 5. Three wires are disposed within a predetermined area in FIG. 4, whereas thinner eight wires are disposed within the same area in FIG. 5.

Even in the case of the metallic wiring pattern caused to be of high density and of ultra fine structure shown in FIG. 5, reaction deposition is apt to be attached to the part in the vicinity of upper surface central part 8, side surface parts 6 and corner parts 10 of aluminum wire 4. For this reason, in the case of metallic wiring patterns of higher density and of ultra finer structure, parts where deposition may be attached become many.

For example, when area in the vicinity of the upper surface central part 208 of the aluminum wire 204 per one wire in FIG. 4 is J, area of side surface parts 206 in terms of both sides is S, and area of corner parts 210 in both sides is G, since three wires exist in FIG. 4, the area of the part where deposition is apt to be attached is expressed as 3×(J+S+G).

In the case of the metallic wiring pattern caused to be of high density and of ultra finer structure shown in FIG. 5, the area of the parts where deposition is apt to be attached is expressed as 8×(J+S+G) (heights of wires are assumed to be the same). Namely, in the case of FIG. 5, as compared to the case of FIG. 4, the area of the part where deposition is apt to be attached is 8/3 (about 2.7) times greater than the latter. Accordingly, it is considered that quantity (volume) of deposition actually attached is about 2.7 times greater than the latter.

Simple extension or acceleration of the related art, i.e., by elongating processing time to increase cleaning solution discharge quantity, or increasing the number of rotations would make it difficult to sufficiently remove deposition in the metallic wiring pattern caused to be of high density and of ultra fine structure.

Further, when cleaning solution processing time is elongated in order to remove deposition, there is the problem that metallic wire which has been formed is deformed by cleaning solution. FIGS. 6(a) and (b) are cross sectional views for explaining this phenomenon. An aluminum wire 4 is formed on insulating film 2, a TiN film 12 is formed on the aluminum wire 4, and a photoresist 14 is mounted on the TiN film 12. From above, a cleaning solution 16 is supplied. When the cleaning solution 16 is supplied for a long time, the photoresist 14 is removed. Since the quantity of fresh cleaning solution 16 in contact with the upper part of aluminum wire 4 is greater than that in contact with the lower part, there takes place the problem that the upper part of the aluminum wire 4 becomes thin so that shaved parts 18 would be formed.

In the case where time of cleaning solution processing is set to be long, there is also the problem that unevenness of processing dependent upon the region of the wafer surface takes place. FIG. 7 is a top view for explaining this phenomenon. Cleaning solution is supplied to a cleaning solution supply position 22 of the center of the surface of wafer 20 rotating in a certain rotation direction 21. The cleaning solution flows from the central part of wafer 20 toward the peripheral part while depicting spiral flow line 24 by the centrifugal force. For this reason, a more fresh cleaning solution is supplied to the wafer central part. Thus, the wafer central part results in a region 26 where reaction activity of cleaning solution is high, and the wafer peripheral part is region 28 where reaction activity of cleaning solution is low. In such a typical wafer processing, in the case where time of processing by cleaning solution is long, there is the problem in which a tendency such that metallic wire becomes thinner in the region 26 where reaction activity is high as compared to the region 28 where reaction activity is low becomes conspicuous.

Further, in the case where pure water is supplied in a rinsing process for removing cleaning solution, when rinsing time is set to be long, there is the problem that aluminum corrosion takes place by the battery effect taking place between pure water and aluminum. By using IPA (Isopropyl alcohol) in place of pure water as rinsing solution, it is possible to prevent aluminum corrosion in the long-time rinsing process. However, there is the problem that IPA is high in terms of cost as compared to pure water.

### SUMMARY

A semiconductor device manufacturing method according to the present invention includes: a step (S1) of implementing etching to a film formed on a semiconductor wafer; and removal steps (S3, S6, S9) of supplying, after etching, a removing solution for removing deposition on the film to the semiconductor wafer in the state of having the number of rotations smaller than a predetermined number of rotations thereafter to rotate the semiconductor wafer at a high number of rotations which is greater than the predetermined number of rotations. This method includes sequences (SE1, SE2, SE3) in which removal process steps are executed twice or more. In this method, total time during which removing solution is supplied is 45 sec. or less.

In accordance with the present invention, deposition removal at fine wiring pattern is performed, and removing solution processing time is short. Thus, there is provided a semiconductor device manufacturing method in which wire thinning is prevented.

### BRIEF DESCRIPTION OF THE DRAWINGS

The above and other objects, advantages and features of the present invention will be more apparent from the following description taken in conjunction with the accompanying drawings, in which:

FIG. 1 shows a manufacturing flow of semiconductor circuit pattern;

FIG. 2 shows a wafer processing apparatus in a known technology;

FIG. 3 shows a wafer processing method in a known technology;

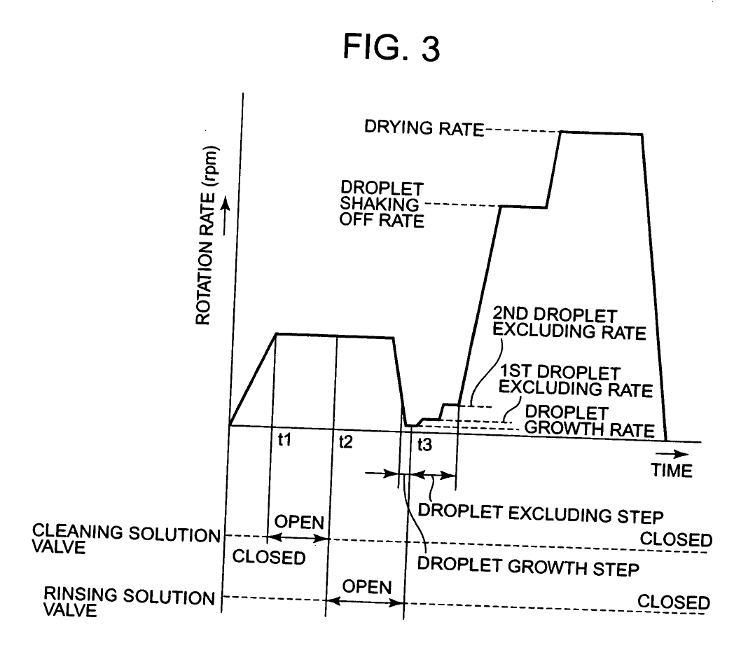

FIG. 4 is a perspective view showing metallic wiring pattern;

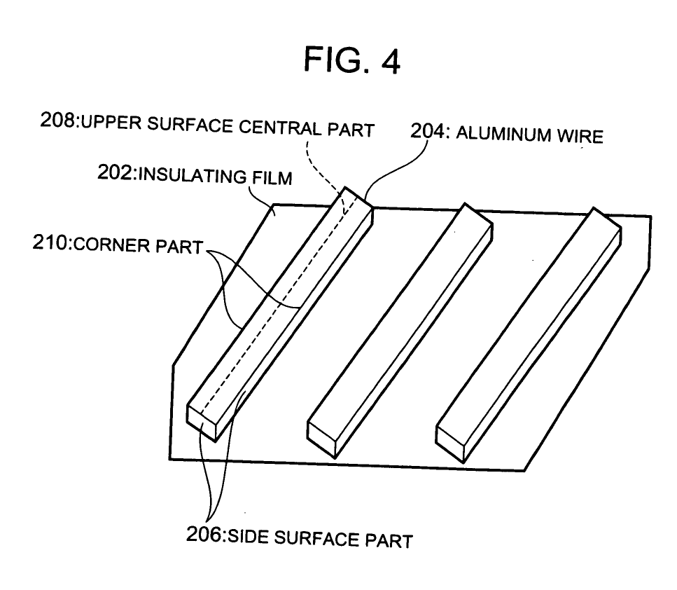

FIG. 5 shows a metallic wiring pattern finer than that of FIG. 4;

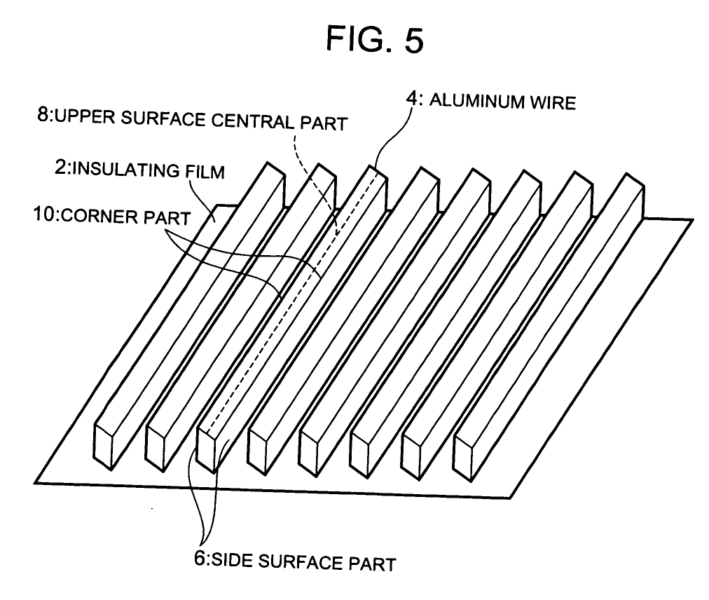

FIGS. 6(a) and 6(b) are diagrams for explaining deformation of metallic wiring by cleaning solution;

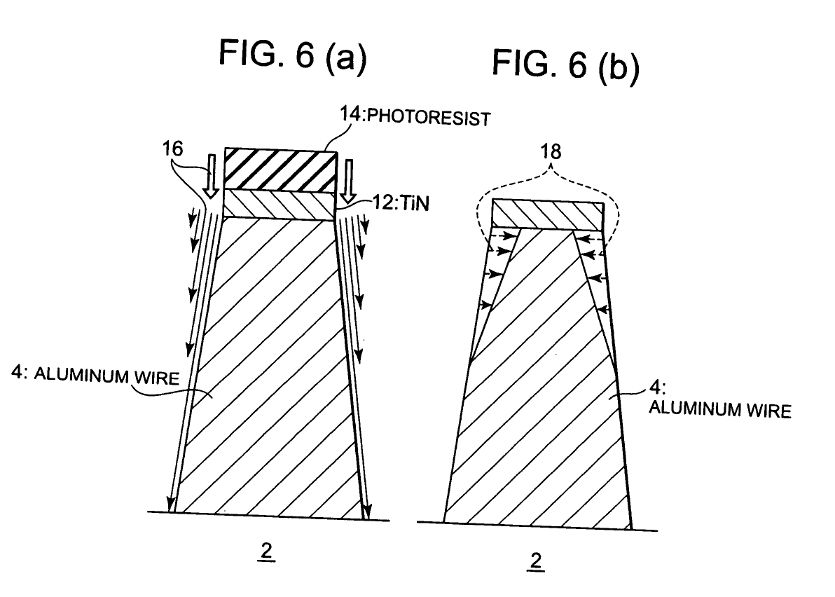

FIG. 7 is a diagram for explaining unevenness of cleaning solution processing depending on region of wafer surface;

FIG. 8 is a flowchart of a semiconductor device manufacturing method;

FIGS. 9(a) and 9(b) are timing charts of wet cleaning process; and

FIG. 10 shows the result of cleaning by repetition of low speed rotation and high speed rotation.

### DETAILED DESCRIPTION OF PREFERRED EMBODIMENTS

The invention will be now described herein with reference to illustrative embodiments. Those skilled in the art will recognize that many alternative embodiments can be accomplished using the teachings of the present invention and that the invention is not limited to the embodiments illustrated for explanatory purposes.

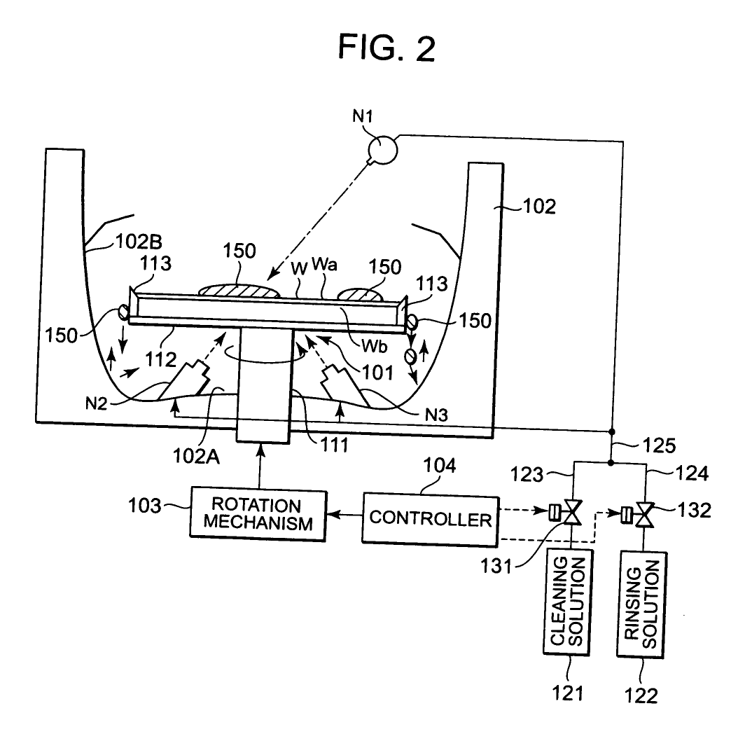

Preferred embodiments for carrying out a semiconductor device manufacturing method in the present invention will now be described in detail with reference to the attached drawings. The semiconductor device manufacturing method in the present invention is executed by a semiconductor wafer processing apparatus including a configuration similar to that of the apparatus shown in FIG. 2. It is to be noted, in this case, control computer program which is read and executed by CPU that a controller 104 includes is different. As a result, control is performed on the basis of recipe different in the number of rotations of spin chuck 101 adjusted by opening of cleaning valve 131 for adjusting supply quantity of cleaning (removing) solution, opening of rinsing solution valve 132 for adjusting supply quantity of rinsing solution (pure water), and rotation mechanism 103.

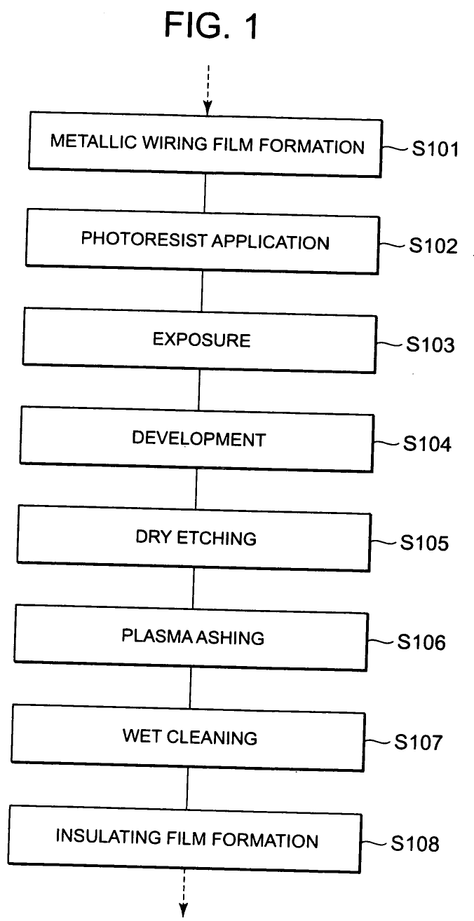

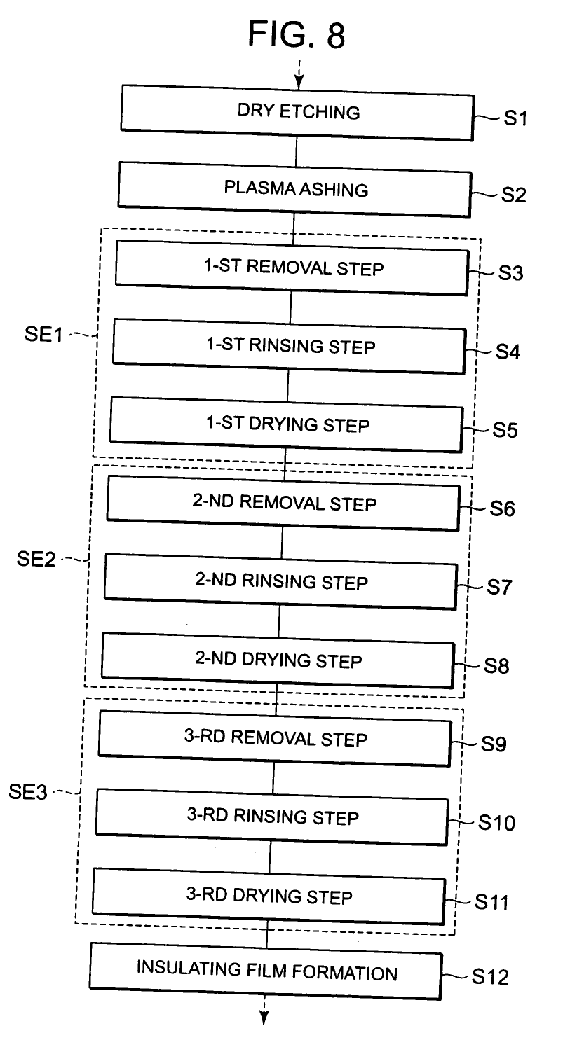

FIG. 8 is a flowchart for explaining the semiconductor device manufacturing method. In this flowchart, there are indicated steps subsequent to development processing (S104) in FIG. 1. The control which will be described below is realized by allowing CPU that the controller includes to read control program that CPU stores in advance to automatically execute processing in accordance with the description of the control program.

A metallic wiring film at the part where photoresist has been removed by development processing is removed by dry etching (S1). For removing the photoresist, plasma ashing is implemented (S2).

After plasma ashing, a first sequence SE1 of wet cleaning process is executed. The first sequence SE1 includes a first removal step S3, a first rinsing step S4 and a first drying step S5.

After the first sequence SE1, a second sequence SE2 of the wet cleaning step is executed. The second sequence SE2 includes a second removal step S6, a second rinsing step S7 and a second drying step 58.

After the second sequence SE2, a third sequence SE3 of the wet cleaning step is executed. The third sequence SE2 includes a third removal step S9, a third rinsing step S10 and a third drying step S11.

After the above-mentioned wet cleaning step is completed, an insulating film is formed on the metallic wiring film in accordance with design (S12).

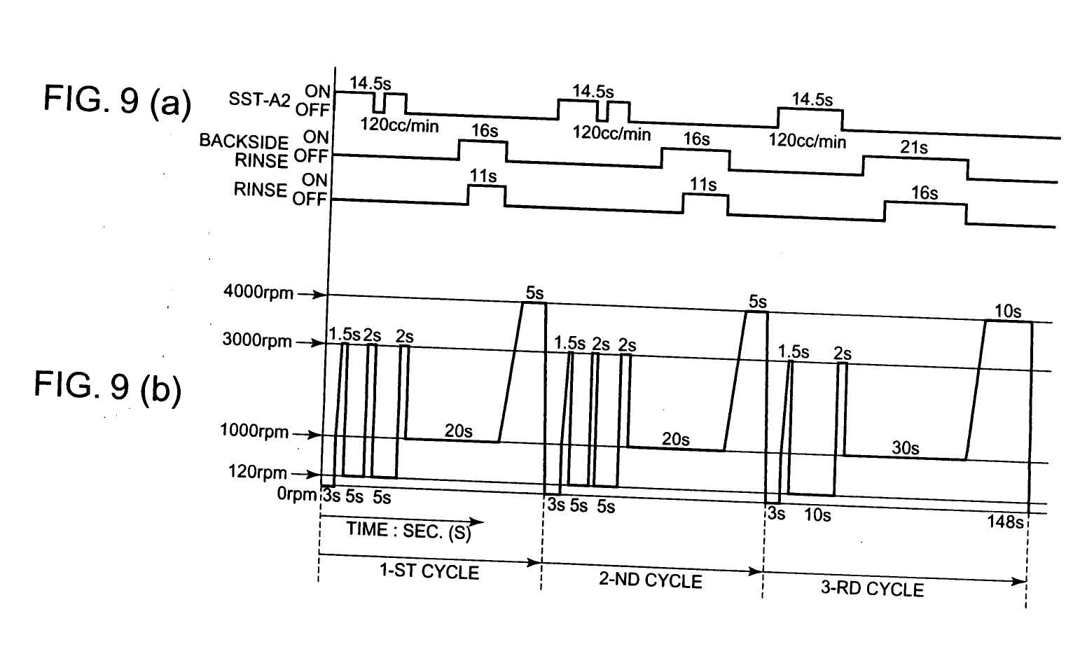

FIG. 9 is a timing chart of wet cleaning step. FIG. 9(a) shows a timing at which removing solution for removing deposition (in the present embodiment, removing solution SST-A2 delivered by Tokyo Ohka Kogyo Co., Ltd. is used) is supplied, a timing at which rinsing solution is supplied to the wafer backside (the side opposite to the surface where elements are formed by etching), and a timing at which rinsing solution is supplied to the element formation side of the wafer. FIG. 9(b) shows the number of rotations of wafer.

First operation: control is performed such that the number of rotations of the wafer becomes equal to 0 rpm, i.e., the wafer is in stationary state at the beginning of the first sequence (described as 1-st cycle in FIG. 9) Removing solution SST-A2 is supplied onto the surface of the wafer. The composition of SST-A2 includes dimethylsulfoxide (CH3)2SO of 68.95 wt %, NH4F of 1 wt %, and water of 30 wt %, which includes hydrofluoric acid (HF).

At the time of the first operation, since the wafer is stationary, there are the merits that solution swollen part of removing solution is concentrically spread, and solution is not moved into the wafer backside (under the condition of 0 rpm, 3 sec. and 120 cc/min.).

Second operation: supply of removing solution to the surface of the wafer is continued. Control is performed such that rotation is made at a high speed for a short time in order to allow the wafer to refresh removing solution. The number of rotations of high speed rotation is controlled so that it falls within the range from 1000 rpm to 4000 rpm. In the example shown in FIG. 9, the number of rotations is 3000 rpm and rotation time is 1.5 sec. By centrifugal force at the time of acceleration until the number of rotations reaches the maximum number of rotations of the high speed rotation, deposition separated from the metallic wiring pattern is moved toward the outside of wafer along with removing solution. Thus, the deposition is removed. In accordance with this operation, in the first operation and the second operation, removing solution which has been used for surface processing of the wafer and has thus become old is rapidly moved toward the outside of the wafer.

Third operation: supply of removing solution to the surface of the wafer is continued. Control is performed such that the wafer is rotated at a low speed. The number of rotations of low speed rotation is set to 120 rpm or less. In this operation, fresh removing solution is admitted into the part between deposition and wire. As a result, at high speed rotation subsequently performed, deposition becomes apt to be separated from the wire and old and deteriorated removing solution is supplied toward the outside of wafer. Thus, the removing solution is refreshed. In the example of FIG. 9, the number of rotations is 120 rpm. Depending upon removing solution and the condition of the wafer surface, the number of rotations may be set to 0 rpm. Under many conditions, in the case where the wafer is rotating, the removing solution is apt to be admitted into the part between deposition and wire. This is effective for refreshing removing solution.

Fourth operation: supply of removing solution to the surface of the wafer is stopped. This stop operation is executed for the purpose of reducing quantity of removing solution used. Accordingly, in the case where use quantity of removing solution is not limited, supply of removing solution may be continued. The wafer is controlled so that it is rotated at a high speed for a short time. The number of rotations of high speed rotation is set similarly as the second operation. In the example of FIG. 9, the number of rotations is 3000 rpm and rotation time is two sec.

Fifth operation: removing solution is supplied to the surface of the wafer. Control is performed such that the wafer is rotated at a low speed. The number of rotations is set similarly as the third operation. In the example of FIG. 9, the number of rotations is 120 rpm.

Sixth operation: supply of removing solution to the surface of the wafer is stopped. This stop operation is executed for the purpose of reducing the quantity of removing solution used similarly to the fourth operation. Control is performed such that the wafer is rotated at a high speed for a short time. The number of rotations of high speed rotation is set similarly as the second operation. In the example of FIG. 9, the number of rotations is 3000 rpm and rotation time is two sec.

The first to the sixth operations correspond to the first removal step S3 in FIG. 8. The durations of the second operation, the fourth operation and the sixth operation where high speed rotation is performed are respectively set to about 1.5 to 2 sec. For a time to this degree, high speed rotation is performed so that removing solution is uniformly spread on the wafer. When this time is too long, there is the possibility that there may take place the problem that removing solution is shaken off from the wafer, or the opportunity where removing solution comes into contact with air becomes many so that the removing solution becomes volatile and the property of the removing solution itself is changed. For this reason, it is desirable that the duration of high speed rotation is set to about 1.5 to 2 sec.

Seventh operation: supply of removing solution is stopped. Control is performed such that the wafer is rotated at a middle speed. In the example of FIG. 9, the number of rotations is 1000 rpm and rotation time is 20 sec. For a time period during which middle speed rotation is performed, rinsing solution (e.g., ultra-pure water) is supplied to the surface of the wafer. In the example of FIG. 9, the length of time period during which rinsing solution is supplied to the surface of the wafer is 11 sec., and the length of time during which backside-rinsing solution is supplied to the wafer backside is 16 sec. This seventh operation corresponds to the first rinsing step S4 in FIG. 8. In order to completely shake off removed deposition or removing solution which has been left on the wafer toward the outside of the wafer, it is desirable that the duration of the middle speed rotation in this operation is set to 10 sec. or more.

The time in which the seventh operation is continued is 20 sec. 11 sec. thereof is time period during which rinsing solution is supplied to the surface of the wafer, and discharge of rinsing solution is not performed for the remaining nine seconds. The reason thereof is indicated below. First, it is already known that there appears the property in which when removing solution SST-A2 in the present embodiment comes into contact with water, aluminum corrosion is hastened. For this reason, it is desirable to sufficiently shake off removing solution SST-A2 on the wafer toward the outside of the wafer prior to discharging rinsing solution (pure water). Second reason is that it is necessary to provide a time required for allowing cleaning solution nozzle arm for controlling the position of the cleaning nozzle which supplies removing solution to return from on the wafer toward the home position outside the wafer.

Eighth operation: both removing solution and rinsing solution are not supplied to wafer. Control is performed such that the wafer is rotated for drying. The rotational speed is set so that rinsing solution on the wafer is shaken off toward-the outside of the wafer. This rotational speed is set to a value larger than that of high speed rotation for refreshing removing solution. In the example of FIG. 9, the rotational speed is 4000 rpm and rotation time is five sec. This eighth operation corresponds to the first drying step S5 in FIG. 8.

The above-mentioned first to eighth operations correspond to the first sequence SE1 of FIG. 8. In the first sequence SE1, total of times during which removing solution is supplied is 14.5 sec.

Subsequently to the first sequence SE1, the second sequence SE2 is executed. As shown in FIG. 9, the operation of the second sequence SE2 is similar to the operation of the first sequence SE1. Also in the second sequence SE2, total of the times during which removing solution is supplied is 14.5 sec.

Subsequently to the second sequence SE2, the third sequence SE3 is executed. The third sequence differs from the first sequence SE1 and the second sequence SE2 in the points described below. The fourth operation (second high speed rotation) is omitted. The duration of the seventh operation (rinsing step) is set to be longer (30 sec. in FIG. 9). The time period during which rinsing solution is supplied to the wafer backside and the time period during which backside-rinsing solution is supplied to the wafer backside are both set to be longer (respectively 16 sec. and 21 sec. in FIG. 9). The duration of the eighth operation (drying step) is set to be longer (10 sec. in FIG. 9). Since the third sequence SE3 is the final sequence, rinsing process and drying process are carefully executed in this way. Except for the points described above, the third sequence SE3 is the same as the first sequence SE1 and the second sequence SE2.

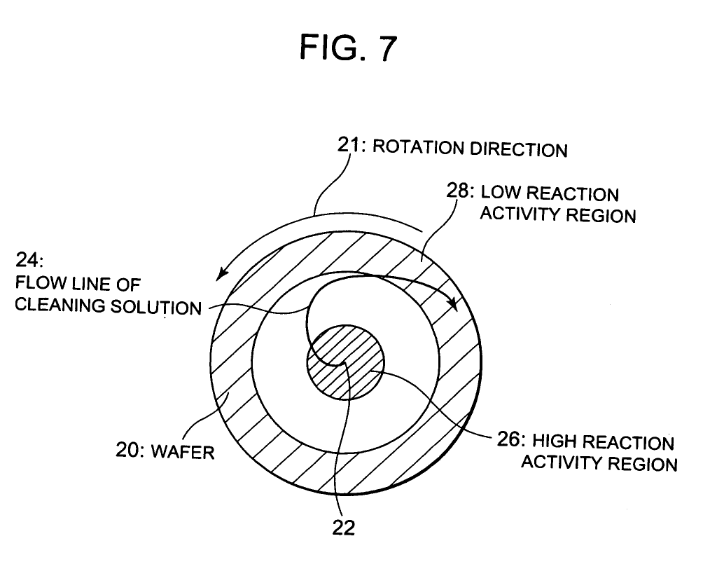

Also in the third sequence SE3, total of the times during which removing solution is supplied is 14.5 sec. similarly to the first sequence SE1 and the second sequence SE2. Setting is made such that total of the times during which removing solution is supplied in all the sequences is 45 sec. or less (43.5 sec. in the present embodiment). By setting supply time of removing solution to 45 sec. or less, thinning of the aluminum wire by removing solution, conspicuousness of aluminum thinning in the vicinity of the wafer central part which has been described with reference to FIG. 7, and aluminum corrosion by pure water rinsing are suppressed, and reduction in processing time and reduction in quantity of processing solution used are attained.

In the present embodiment, the sequence including removing step (removal step), rinsing step and drying step was repeated three times. When the total removing solution processing time is set to 45 sec. or less and setting is made such that rinsing step is performed for 10 sec. or more in order to perform rinsing sufficiently, it is most suitable that the number of repetitions of sequences is three.

In the above-mentioned processing, temperature of removing solution supplied to the wafer is set to a value within the range from 35° C. to 45° C. In the related art, temperature of removing solution was set to, e.g., about 25° C. However, the inventor has found that the deposition removable ability when temperature of removing solution (e.g., SST-A2) is set to the range from 35° C. to 45° C. is higher than that when temperature of the removing solution is set to about 25° C. In the present embodiment, since it is an object to set removing solution processing time to be short to perform removing in order to prevent corrosion of metal by removing solution, it is important to use removing solution at a temperature where deposition removal ability is as high as possible.

The inventor has actually confirmed by the example shaking experiment, and the electron microscopic observation of deposition remaining state of metallic wiring pattern that removal effect of deposition in the case where temperature of removing solution is set to 35° C., 40° C. and 45° C. is 3.5 times greater than that in the case where temperature of removing solution is set to 25° C.

There are indicated below data obtained by observing, by using SEM (Scanning Electron Microscope), the number of points where there is deposition remaining part when temperature of removing solution is set to 25° C., 35° C. and 45° C. in the case where wafer having fifteen points of depositions per one wafer is cleaned by removing solution.

25° C.: Number of deposition remaining points 14

35° C.: Number of deposition remaining points 4

45° C.: Number of deposition remaining points 7

Cleaning effect in the case where temperature of removing solution is set to 35° C. or 45° C. is high as compared to the case where temperature of removing solution is set to 25° C. Particularly, it is desirable that temperature of removing solution is set to a value in the vicinity of 35° C.

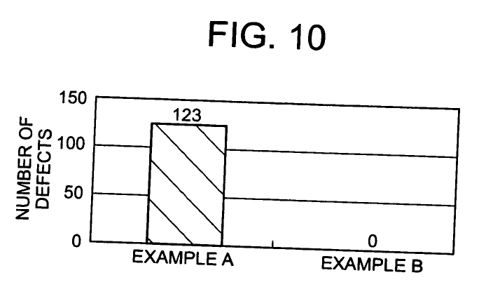

FIG. 10 is a diagram for explaining cleaning effect obtained by repeating processing including low speed rotation and high speed rotation continuous thereto as in the case of the above-described first to sixth operations. Example A indicates the case where removing solution processing and rinsing process steps are respectively repeated two times without performing processing to repeat low speed rotation and high speed rotation. After cleaning of the example A, 123 defects exist on wafer. Example B indicates the case where processing to repeat, several times, low speed rotation and high speed rotation to repeat removing solution processing and rinsing step as indicated in the present embodiment. After cleaning of the example B, any defect is not found by any means on the wafer.

What is claimed is:

1. A method of manufacturing a semiconductor device comprising:
forming a film on a semiconductor wafer;
forming a mask film on the film;
etching the film using the mask; and
cleaning the wafer after etching the film, the cleaning step including a sequence supplying removing solution to the wafer while a removal step having plural operations including rotating the wafer at a first number of rotation and a rotating the wafer at a second number of rotation which is larger than the first number of rotation is performed,
wherein the total time of supplying the removing solution in the cleaning step is 45 seconds or less.

2. The method of manufacturing a semiconductor device according to claim 1,
wherein the sequence is executed twice or more.

3. The method of manufacturing a semiconductor device according to claim 1,
wherein the second number of rotation is set to be from 1000 rpm to 4000 rpm.

4. The method of manufacturing a semiconductor device according to claim 1,
wherein, in first of the operations, the first number of rotation is set to be 0 rpm.

5. The method of manufacturing a semiconductor device according to claim 1,
wherein the first number of rotation is set to be larger than 0 rpm and is 120 rpm or less.

6. The method of manufacturing a semiconductor device according to claim 1,
wherein temperature of the removing solution supplied to the semiconductor wafer is set to be from 35° C. to 45° C.

7. The method of manufacturing a semiconductor device according to claim 1,
wherein the sequence includes a rinsing step of supplying, for 10 sec. or more, a rinsing solution for removing the removing solution.

8. The method of manufacturing a semiconductor device according to claim 1,
wherein, in a part of the removal step included in the sequence, supply of the removing solution is stopped.

9. The method of manufacturing a semiconductor device according to claim 8,
wherein removing solution is stopped while rotating the wafer at a second number of rotation.

10. The method of manufacturing a semiconductor device according to claim 1,
wherein the removing solution is including hydrofluoric acid.

11. The method of manufacturing a semiconductor device according to claim 1,
wherein the film is including aluminum.

12. A method of manufacturing a semiconductor device comprising:
forming a film on a semiconductor wafer;
forming a mask film on the film;
etching the film using the mask; and
cleaning the wafer to remove deposition, the cleaning step including a sequence supplying removing solution on the wafer while a removal step having plural operations including rotating the wafer at a first number of rotation and a rotating the wafer at a second number of rotation which is larger than the first number of rotation is performed,
wherein the sequence further including a rinsing step rotating the wafer at a third number of rotation whose number is greater than the first number of rotations and smaller than the second number of rotations.

13. The method of manufacturing a semiconductor device according to claim 12,
wherein the sequence is executed twice or more.

14. A method of manufacturing a semiconductor device, comprising:
performing a selective etching operation on a semiconductor wafer to produce an intermediate semiconductor wafer; and
performing a cleaning operation on the intermediate semiconductor wafer;
the cleaning operation is performed by carrying out a sequence a plurality of times, the sequence comprising a removal step, a rinsing step and a drying step, the removal step including supply of a removing solution to the intermediate semiconductor wafer, the rinsing solution including supply of a rinsing solution to the intermediate semiconductor wafer, the removing solution being thereby supplied to the intermediate semiconductor wafer a plurality of times during the cleaning operation, and a total period of time when the removing solution is being supplied to the intermediate semiconductor wafer during the cleaning operation is 45 seconds or less.

15. The method as claimed in claim 14, wherein the removal step including a first operation, a second operation following the first operation, a third operation following the second operation, and a fourth operation following the third operation, the intermediate semiconductor wafer being rotated at a first speed during the first operation, at a second speed higher than the first speed during the second operation, at a third speed lower than the second speed during the third operation, and at a fourth speed higher than the third speed during the fourth operation.

16. The method as claimed in claim 15, the first speed is zero and the third speed is larger than zero.

17. The method as claimed in claim 15, wherein the intermediate semiconductor wafer is rotated at a fifth speed during the rinsing step, the fifth speed is higher than each of the first and second speeds.

18. The method as claimed in claim 15, wherein the intermediate semiconductor wafer is rotated at a fifth speed during the rinsing step for a predetermined period of time which is longer than each of the first to fourth operations.

19. The method as claimed in claim 14, wherein the sequence is carried out three times, a period of time when the removing solution is being supplied to the intermediate semiconductor wafer is 15 seconds or less per one sequence.

20. The method as claimed in claim 19, wherein the supply of the removing solution to the intermediate semiconductor wafer is suspended and then resumed during the removal step of one sequence.
